(19) United States
(12) Patent Application Publication
(10) Pub. No.: US 2003/0111700 A1
(43) Pub. Date: Jun. 19, 2003

(54) Method and article of manufacture for micro-lens resulting from multi-stage fabrication technique

(76) Inventor: Selim S. Bencuya, Irvine, CA (US)

Correspondence Address: Jack J'maev, 12616 Lewis Ave, Chino, CA, 91710, US

(21) Appl. No.: 10/016,713

(22) Filed: Nov. 2, 2001

(51) Int. Cl. H01L 21/00; H01L 31/0232

(52) U.S. Cl. 257/432; 438/48; 438/65; 359/619

(57) ABSTRACT

Micro-lenses are formed on the surface of a semiconductive circuit through a plurality of processing stages. In each stage, an alternate lens placement pattern is imparted onto micro-lens suitable material. Unwanted material is removed and micro-lenses are formed from the remaining material. Subsequent stages are applied until all desired micro-lenses in a structure are defined and formed from alternate placement patterns.

### FIELD OF THE INVENTION

This invention relates generally to micro-lenses employed in semiconductor devices.

### BACKGROUND OF THE INVENTION

Various semiconductive circuits exist today for detecting radiation. In the simplest embodiment of these types of devices, a single detector can be constructed on a monolithic substrate for detecting radiation. Typical of these single detector devices are infrared detectors commonly used as the receiving element in remote control systems. Radiation detectors constructed for the purpose of detecting visible radiation, i.e. light, can comprise charge coupled devices (CCD) and complimentary metal on semiconductor (CMOS) semiconductive devices organized in large arrays in order to detect images. These devices can be structured in linear or two-dimensional arrays.

Linear sensors are normally used in applications such as level detectors. One common application is that of laser ground leveling systems used in the construction trades. Two-dimensional arrays are even more abundant in cameras.

The technology of CCD and CMOS image sensors is not limited to the visible light spectrum. Many semiconductor devices are constructed to detect near-infrared and other non-visible radiation. Night vision systems utilize these types of image detectors as their primary sensing elements.

Irrespective of the spectrum of sensitivity or the application of these versatile image sensors, the semiconductive circuits that embody them typically include not only the sensing elements themselves, but also other circuitry used to receive the signals generated by the sensing elements. In a monolithic semiconductor structure comprising such devices, only a fraction of the surface area may actually be sensitive to radiation.

Because in some applications such a small portion of the surface area of a semiconductive radiation sensor is actually active, focusing structures may be used to direct an image to the sensitive regions. In traditional fashion, directing radiation to the sensitive regions of a semiconductive detector may be done through the use of lenses. In modern image sensor arrays, each sensitive region may be capped with a so-called “micro-lens”.

Micro-lenses can be fabricated by depositing, for example, a clear photo-resist material formulated to enhance optical transmissivity. Any suitable micro-lens material may be used in lieu of a photo-resist. The micro-lens suitable material is subjected to a single lens formation pattern that defines a plurality of “islands”. These islands are formed on the semiconductive circuit after unwanted material is removed. Because formation of the micro-lenses relies on a reflow process, it is typically necessary to provide some physical separation between the islands. The amount of physical separation thus required is driven by several factors including, but not limited to the surface tension of the material and other reflow and capillary characteristics.

One other factor that drives the amount of physical separation required between each individual island of micro-lens suitable material is that of the resolution that may be achieved when the lens formation pattern is imparted onto the material to define island placement. Some amount of image bleeding will occur during this process. Hence, the amount of space required between the islands of micro-lens suitable material must be great enough to accommodate this resolving inaccuracy.

### SUMMARY OF THE INVENTION

The present invention comprises a method for forming micro-lenses on a semiconductive circuit. In one embodiment, a novel aspect of the present invention is the notion of forming micro-lenses in two or more stages. In each stage, a coat of micro-lens suitable material is applied to the surface of a semiconductive circuit. One of a plurality of lens formation patterns is imparted onto each coat of micro-lens suitable material and a plurality of micro-lenses is formed therefrom. In some embodiments of this method, the lens formation patterns are alternate counterparts of each other.

In one example method according to the present invention, a first coat of micro-lens suitable material is applied to the top surface of a semiconductive circuit. After this first coat of micro-lens suitable material is applied, a first lens-formation pattern is imparted thereon. Imparting the first lens formation pattern may be accomplished using photographic techniques. This may be true when the micro-lens suitable material comprises an optically transmissive photo-resist.

After the first lens formation pattern is imparted onto the first coat of microlens suitable material, unwanted portions of the material are removed. This results in a plurality of islands of micro-lens suitable material that remain adhered to the surface of the semiconductive circuit. The next step in this example method is that of forming a first plurality of micro-lenses out of the islands of micro-lens suitable material remaining from the first coat.

Once the first plurality of micro-lenses is created, this example method provides for application of a second coat or subsequent coats of micro-lens suitable material on to the surface of the semiconductive circuit. A second lens-formation pattern may be imparted onto the second coat of micro-lens suitable material. This second lens-formation pattern defines a second plurality of islands of micro-lens suitable material. Unwanted portions of the second coat of micro-lens suitable material may then be removed. After removal, a second plurality of islands of microlens suitable material remains adhered to the surface of the semiconductive circuit. This example method of the present invention concludes with a step for forming a second plurality of micro-lenses. The second plurality of islands of micro-lens suitable material is formed into a second plurality of micro-lenses.

In one variant of this example method, the first and second lens-formation patterns may comprise alternate counterparts of each other. By using such alternate counterpart patterns, the overall size of each micro-lens can be maximized because the alternate counterpart patterns obviate the need for any exposure resolution setback normally required in prior single-pass techniques. In yet a different variant of this example method, the first and second lens-formation patterns may comprise rectangular regions set out in a checkerboard pattern. Again, these may be counterparts of each other. In some processes, use of this type of a checkerboard pattern may not entirely relieve the potential for capillary action between neighboring islands of micro-lens suitable material. To further preclude such capillary action, one variant method according to the present invention provides that the rectangular regions set forth in the checkerboard patterns comprise broken corners. This avoids any continuity between neighboring rectangular regions in the pattern. It should be noted that any suitable geometric shape may be used in lieu of rectangular shapes in any lens formation pattern.

Additional variation to this example method may comprise different techniques for forming the first and second plurality of micro-lenses. One such example lens forming technique comprises raising the temperature of the micro-lens suitable material in order to relieve the surface tension of the material. This facilitates reflow of the material. The reflow action may be controlled in order to achieve any desired focal length for the resulting micro-lenses. The temperature of the material can then be reduced in order to maintain micro-lens shape and focal length thus achieved.

The example method described herein can be modified in some cases to provide for application of the plurality of coats of micro-lens suitable material through a spin-coating process. This results in a uniform layer of material deposited on the surface of the semiconductive circuit. The example method may also utilize different techniques to impart one of a plurality of lens-formation patterns on to the plurality of coats of micro-lens suitable material. One such method of imparting the a lens-formation pattern may comprise placing a formation mask proximate to the coat of photo-resist and aligning this formation mask relative to the semiconductive circuit. Once aligned, the formation mask is irradiated to impart the lens formation pattern onto the micro-lens suitable material.

The present invention also comprises a second example method for forming micro-lenses in a multiple stage process. This second illustrative method comprises a first step of applying a first coat of micro-lens suitable material to the surface of a semiconductive circuit. A first lens-formation pattern may then be imparted onto the first coat of micro-lens suitable material. Unwanted portions of the first coat of micro-lens suitable material may then be removed. This results in a first plurality of islands of micro-lens suitable material that remain adhered to the surface. In this second example method, a second coat of micro-lens suitable material may then be applied to the surface. This second coat of micro-lens suitable material is subjected to a second lens-formation pattern. Again, unwanted portions of the second coat of micro-lens suitable material are removed. This results in a second plurality of islands of micro-lens suitable material. The remaining portions of the first and second coats of micro-lens suitable material are used to form a single lot of micro-lenses.

The present invention further comprises a micro-lens structure comprising a plurality of micro-lenses positioned so as to direct radiation to a plurality of radiation sensitive active regions formed in a semiconductive circuit. In this example embodiment of the present invention, each active region may be formed within a boundary region perimeter. This boundary region perimeter defines an area of the semiconductive circuit that comprises not only the radiation sensitive active region, but also the ancillary circuitry necessary to detect the amount of radiation reaching the active regions. According to this embodiment, micro-lenses are formed from islands of micro-lens suitable material deposited on to the surface of the semiconductive circuit. Further distinguishing the present invention according to this example of embodiment, each of these islands of micro-lens suitable material occupies an area within the boundary region perimeter that is larger than any exposure resolution setback ordinarily associated with imparting lens formation patterns onto the microlens suitable material in a single pass.

The micro-lens structure comprising the present invention may be fabricated by first depositing islands of micro-lens suitable material on to the surface and then forming micro-lenses therefrom. The islands of micro-lens suitable material may be applied in two or more steps according to the method of the present invention.

The present invention further comprises a semiconductive image sensor. According to this illustrative embodiment, the semiconductive image sensor may comprise a surface, a plurality of radiation sensitive active regions in the surface, sensing circuitry that is used to sense the amount of radiation reaching the active regions, and a plurality of micro-lenses disposed proximate to and coincident with the plurality of active regions. According to this example embodiment, each island of micro-lens suitable material occupies an area within a boundary perimeter surrounding the active region that is greater than that associated with imparting lens formation patterns onto the micro-lens suitable material in a single pass. According to this example embodiment, each micro-lens may be formed from an island of microlens suitable material deposited on to the surface of the semiconductive image sensor in multiple stages according to the method of the present invention.

### BRIEF DESCRIPTION OF THE DRAWINGS

The foregoing aspects are better understood from the following detailed description of one embodiment of the invention with reference to the drawings, in which:

FIG. 1 is a pictorial representation of a traditional linear image sensor;

FIG. 2 is a pictorial representation of a lens formation pattern used in creating microlenses for a linear image sensor;

FIG. 3 is a cross sectional representation of islands of micro-lens suitable material created after unwanted material is removed;

FIG. 4 is a cross sectional representation of islands of micro-lens suitable material after a lens-forming process;

FIG. 5 is pictorial representation of a two-dimensional image sensor;

FIG. 6 is a pictorial representation of a lens formation pattern used in creating microlenses for a two-dimensional image sensor;

FIG. 7 is also a pictorial representation depicting the arrangement of active regions forming a linear image sensor;

FIG. 8 is a pictorial depiction of a first lens-formation pattern used in one example method of the present invention for forming micro-lenses on linear image sensors;

FIG. 9 is pictorial depiction of a second lens-formation pattern used in this example method of the present invention for forming micro-lenses on linear image sensors;

FIG. 10 is a pictorial representation depicting the arrangement of active regions forming a two-dimensional image sensor;

FIG. 11 is a pictorial depiction of a first lens-formation pattern used in one example method of the present invention for forming micro-lenses on two-dimensional image sensors;

FIG. 12 is a pictorial depiction of a second lens-formation pattern used in this example method of the present invention for forming micro-lenses on two-dimensional image sensors;

FIG. 13 is a pictorial representation of a modified rectangular region that may be used in some embodiments of a first, second or subsequent lens-formation pattern according to the present invention;

FIG. 14 is a pictorial representation of a lens-formation pattern comprising modified rectangular regions according to some example embodiments of the present invention;

FIG. 15 is a flow diagram that summarizes one example method of fabricating microlenses according to the present invention;

FIG. 16 is a perspective view depicting islands of micro-lens suitable material that remain adhered to the top surface of a semiconductive circuit after unwanted material is removed; and

FIG. 17 is a continuation of the flow diagram presented in FIG. 15 that depicts one example method of fabricating micro-lenses according to the present invention.

### DETAILED DESCRIPTION OF THE INVENTION

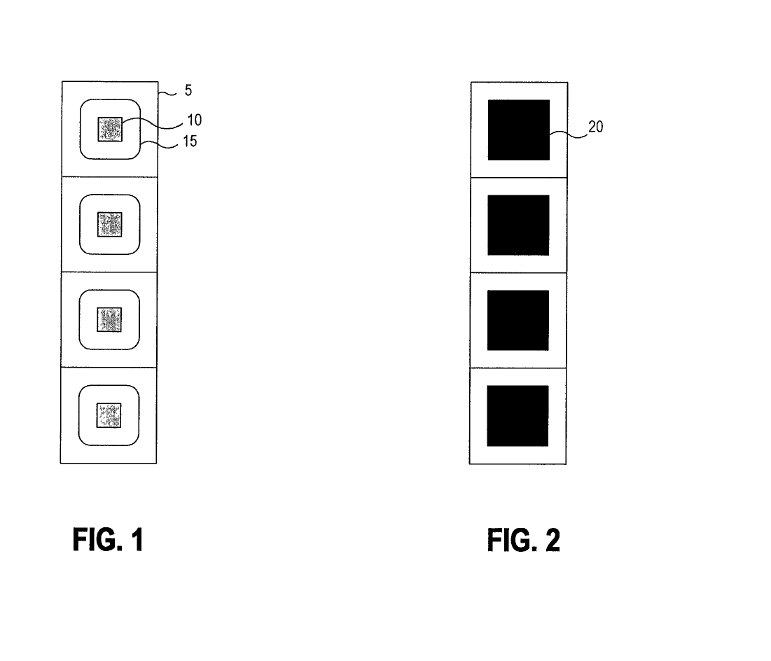

FIG. 1 is a pictorial representation of a traditional linear image sensor. Such linear image sensors may comprise a plurality of active regions 10 arranged in a linear fashion. The active regions 10 are sensitive to radiation in one form or another. One important feature to note with respect to the linear sensor is the fact that each active region 10 may be located within a larger boundary region 5. The reason that this boundary region 5 exists is to accommodate the various circuitries necessary to sense the state of the active region 10.

Because the active region 10 may make up only a small portion of the area lying within the boundary region 5, it is advantageous to improve the field of view for each active region 10. This may be accomplished by introducing a lens 15 disposed immediately above each active region 10. Ideally, the area occupied by the lens 15 should be substantially greater than the area of the active region 10. This allows more of the radiation striking the surface of the image array to reach the actual active region 10.

FIG. 2 is a pictorial representation of a lens formation pattern used in creating micro-lenses for a linear image sensor. The lenses disposed immediately above each active region 10 in a linear image sensor are referred to as “micro-lenses”. These micro-lenses may be formed by depositing a layer of micro-lens suitable material upon the substrate comprising the linear image sensor. The micro-lens suitable material may comprise a photo-resist that is formulated specifically for the fabrication of micro-lenses and is optimized to promote optical transmissivity.

The geometry of the exposure pattern normally comprises a plurality of rectangular shapes 20 each coincident within an active region 10. Each rectangular shape 20 in the exposure pattern is distinct from every other rectangular shape in that exposure pattern.

Once the entire surface of the linear image sensor is covered with micro-lens suitable material, a lens formation pattern that defines the placement of micro-lenses relative to the substrate is imparted onto the material. Any material not defined by the lens formation pattern may be removed. Where a photo-resist is used, a development process may be used to remove unwanted photo-resist and leave distinct islands of optically transmissive photo-resist on the substrate.

One undesirable artifact of the exposure process is the relatively poor resolving power of the micro-lens suitable material itself. This means that as the micro-lens suitable material is subjected to a lens formation pattern, some amount of bleeding will occur. The lens formation pattern must accommodate this inherent bleeding phenomenon. Accommodation of the bleeding may be accomplished by making the rectangular shapes 20 somewhat smaller than the outer perimeter of the boundary region 5 encompassing each active sensing region 10. This setback precludes the formation of micro-lenses that occupy the entire area defined by the boundary region 5. This results in a diminished efficiency for any micro-lens array fabricated using traditional techniques.

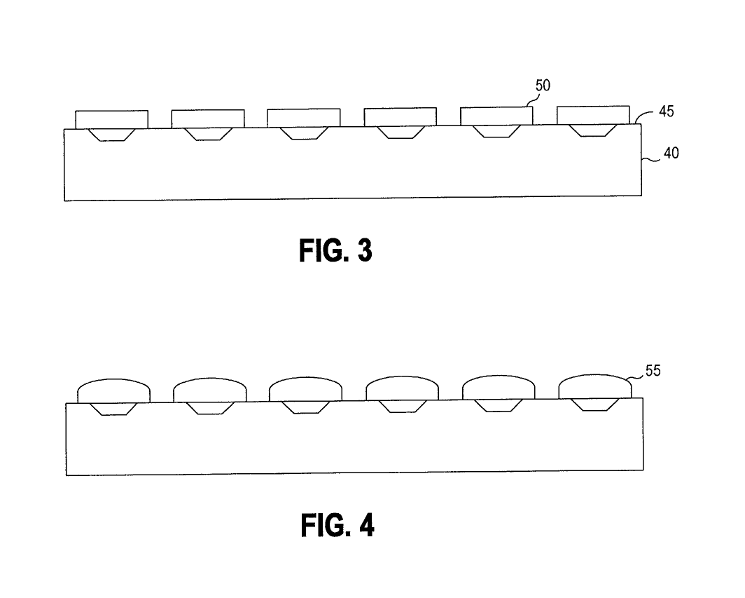

FIG. 3 is a cross sectional representation of islands of micro-lens suitable material created after unwanted material is removed. In cross-section, an image sensor may comprise a semiconductive substrate 40. The semiconductive substrate 40 may comprise a plurality of active regions 10. The top surface 45 of the semiconductive circuit 40 is first coated with micro-lens suitable material and then subjected to the lens formation pattern. After the unwanted portion of the micro-lens suitable material is removed, as defined by the lens formation pattern, a plurality of islands 50 of micro-lens suitable material remain adhered to the semiconductive substrate 40.

FIG. 4 is a cross sectional representation of islands of micro-lens suitable material after a lens-forming process. The islands 50 of micro-lens suitable material remain adhered to the semiconductive substrate 40 after unwanted material is removed. In order to form micro-lenses from these islands 50, the temperature of the micro-lens suitable material may be raised in order to relax the surface tension thereof. When the surface tension is relaxed, the micro-lens suitable material comprising the islands begins to reflow. The amount of reflow, which is a function of the temperature and the duration of exposure to that temperature, determines the focal length of an optically focused micro-lens 55.

FIG. 5 is pictorial representation of a two-dimensional image sensor. In the two-dimensional image sensor, active regions 10 may again be encompassed within a boundary perimeter 5. The two-dimensional image sensor may further comprises a micro-lens 15 disposed above each active region 10. This two-dimensional structure is essentially analogous to the linear structure depicted in FIG. 1. In a like manner, each micro-lens 15 may be formed from an island of micro-lens suitable material.

FIG. 6 is a pictorial representation of a lens formation pattern used in creating micro-lenses for a two-dimensional image sensor. In this pattern, rectangular shapes 20 are arranged in array. Again, due to the bleeding phenomenon that occurs during processing of the micro-lens suitable material deposited on the semiconductive substrate, a setback 60 must be introduced between the rectangular shapes 20 and the boundary perimeter 5. This setback 60 ensures that the micro-lens suitable material will form distinct islands after any unwanted material is removed. It is important to note that this setback limits the overall size of any micro-lens 15 that may be formed from each island of micro-lens suitable material.

FIG. 7 is also a pictorial representation depicting the arrangement of active regions forming a linear image sensor. FIG. 8 is a pictorial depiction of a first lens-formation pattern used in one example method of the present invention for forming micro-lenses on linear image sensors. FIG. 9 is pictorial depiction of a second lens-formation pattern used in this example method of the present invention for forming micro-lenses on linear image sensors. According to this example method, a first lens-formation pattern is used to define the placement of a first plurality of micro-lenses in a linear image sensor application. This first lens-formation pattern comprises rectangular regions 20 that substantially fill the entire boundary region 5 of each image sensor elements, i.e. an active region 10.

In this example method, the first lens-formation pattern omits the rectangular regions in any boundary region 5 immediately neighboring any given boundary region 5. By omitting every other rectangular region, the area of the islands of micro-lens suitable material maybe maximized because there's no longer a need for an exposure setback. The second lens-formation pattern also comprises rectangular regions 20. The placement of rectangular regions 20 in the second lens-formation pattern is structured to form a pattern that is an alternative counterpart of the first lens-formation pattern. This means that lens placements not defined in the first lens formation patterns are specified in the second lens formation pattern. Lens placements not defined in the second lens formation pattern are specified in the first pattern.

According to one example method of the present invention, the first lens-formation pattern is used to define the placement of a first plurality of micro-lenses that are formed from a first coat of micro-lens suitable material. Once the first plurality of micro-lenses are formed, a second coat of micro-lens suitable material is applied to the surface of the linear image sensor. The second lens-formation pattern is used to define the placement of a second plurality of micro-lenses that are formed from the second coat of micro-lens suitable material.

FIG. 10 is a pictorial representation depicting the arrangement of active regions forming a two-dimensional image sensor. FIG. 11 is a pictorial depiction of a first lens-formation pattern used in one example method of the present invention for forming micro-lenses on two-dimensional image sensors. FIG. 12 is a pictorial depiction of a second lens-formation pattern used in this example method of the present invention for forming micro-lenses on two-dimensional image sensors. A two-dimensional array of active regions 10 forms a two-dimensional image sensor that may be typically used in cameras. However, this one specific example application is not intended to limit the scope of the present invention. Each active region 10 may be encompassed within a boundary perimeter 5.

A first lens-formation pattern is used to define the placement of a first plurality of micro-lenses in a two-dimensional image sensor. In the case of an orthogonal array of active regions 10, the first lens-formation pattern may comprise a plurality of rectangular regions set forth in a checkerboard pattern. Each rectangular region 20 substantially fills the entire boundary region 5 of the rectangular region's corresponding active region 10. A second lens-formation pattern may be used to define the placement of a second plurality of micro-lenses in the two-dimensional image sensor. This second lens-formation pattern may comprise rectangular regions 20 set forth in a checkerboard pattern comprising an alternative counterpart of the first lens-formation pattern. The first and second lens-formation patterns are used in two distinct lens fabrication stages as described infra.

FIG. 13 is a pictorial representation of a modified rectangular region that may be used in some embodiments of a first, second or subsequent lens-formation pattern according to the present invention. Using the standard rectangular region 20, the resulting checkerboard pattern for a lens-formation pattern useful in defining the placement of micro-lenses in any two-dimensional image sensor may contain continuities. Each rectangular region in the pattern may be connected to neighboring rectangular regions by virtue of their corners touching. Such continuity may adversely affect the formation of micro-lenses during the reflow process. This continuity may be eliminated by breaking the corners of each rectangular region in any first, second or subsequent lens-formation pattern. Broken corners 70 may be embodied as rounded corners, chamfered corners, or any other geometric configuration suitable to accomplish a break in continuity in the resulting lens-formation pattern.

FIG. 14 is a pictorial representation of a lens-formation pattern comprising modified rectangular regions according to some example embodiments of the present invention. When rectangular regions 20 comprising broken corners 70 are used in any lens-formation pattern, neighboring rectangular regions no longer touch each other. This results in a distinct gap 75 between each rectangular region. This gap precludes continuity in the pattern.

It is important to note that any of the plurality of lens formation patterns may comprise varying geometric shapes and that the scope of the present invention is not intended to be limited to the use of rectangular regions. Also, the notion of using patterns that are alternate counterparts of each other is one distinguishing characteristic of the present invention. Where two lens formation patterns are used, a checkerboard pattern may be used. As more processing steps are used, further separation between lens placements can be envisioned amongst the plurality of lens formation patterns. The lens formation patterns comprising the plurality may collectively define all desired lens placements in a particular application.

FIG. 15 is a flow diagram that summarizes one example method of fabricating micro-lenses according to the present invention. This example method may be used to fabricate a micro-lens structure comprising an array of micro-lens in a two-stage process using two lens formation patterns, but this example may be expanded to comprise additional processing steps using additional lens formation patterns. This example method may also be used to fabricate an image sensor comprising such a micro-lens structure. Any image sensor typically comprises a plurality of active regions 10 disposed on the top surface of a semiconductive circuit.

The first step in this example process comprises application of a first coat of micro-lens suitable material to the surface (step 80). This micro-lens suitable material may typically be formulated specifically for use in micro-lens formation; having enhanced optical transmissivity. In some variations of the method of the present invention, any layer of micro-lens suitable material may be applied using a spin-coating process.

Once the first coat of micro-lens suitable material is applied to the top surface of the semiconductive circuit, it may be subjected to a first lens-formation pattern (step 85). For a typical two-dimensional image sensor, the first lens-formation pattern may comprise a checkerboard pattern comprising a plurality of rectangular regions. The rectangular regions may or may not comprise broken corners. In one variation of this method, exposure of the first coat of micro-lens suitable material to the first lens-formation pattern may be accomplished by placing a first formation mask comprising the first lens-formation pattern proximate to the first coat of micro-lens suitable material. The first formation mask is that aligned relative to the semiconductive circuit and irradiated to impart the first lens-formation pattern onto the first coat of micro-lens suitable material.

FIG. 16 is a perspective view depicting islands of micro-lens suitable material that remain adhered to the top surface of a semiconductive circuit after unwanted material is removed. After the first coat of micro-lens suitable material is subjected to the first lens-formation pattern, unwanted material is removed (step 90). This process may typically wash away unwanted micro-lens suitable material from the first coat. What remains after removal of unwanted material is the substrate 40 comprising a top surface 45 and a plurality of islands 50 of micro-lens suitable material adhered to the top surface 45 in a checkerboard pattern.

It should be noted that the area occupied by each island of micro-lens suitable material may be as large as the boundary perimeter 5 encompassing each active region 10. One feature that distinguishes the islands 50 of the present invention is the fact that they may be larger than any setback ordinarily necessary to accommodate bleeding that may occur during the process of imparting a lens-formation pattern to any coat of micro-lens suitable material as used in a single stage fabrication technique.

FIG. 15 further shows that once unwanted material from the first coat of microlens suitable material is removed, a first plurality of micro-lenses is formed (step 95) from the plurality of islands adhered to top surface of the semiconductive circuit according to the first lens-formation pattern. Formation of micro-lenses is typically accomplished by raising the temperature of the islands of micro-lens suitable material in order to relax its surface tension. Once the surface tension is relaxed, the microlens suitable material reflows and takes on the shape of a focused lens. Once the desired focal length is achieved, the reflow process may be arrested by reducing the temperature of the islands of micro-lens suitable material.

FIG. 17 is a continuation of the flow diagram presented in FIG. 15 that depicts one example method of fabricating micro-lenses according to the present invention. This example method continues by applying a second coat of micro-lens suitable material to the top surface of the semiconductive circuit (step 105). This second coat of micro-lens suitable material is then subjected to a second lens formation pattern (step 110). In most applications of this example method, the second lens-formation pattern comprises an alternate counterpart of the first lens-formation pattern. In other variations of this example method, the first and second lens-formation patterns comprise rectangular regions set forth in a checkerboard pattern. In some cases, the rectangular regions set forth in the checkerboard pattern may comprise broken corners so as to avoid continuity throughout the pattern of photo-resist islands defined by the checkerboard pattern. Again, the scope of the present invention should not be limited to use of rectangular regions in any lens formation pattern. Any suitable geometric shape may be used.

After exposure, the second coat of micro-lens suitable material is processed to remove unwanted material (step 115). A second plurality of islands of micro-lens suitable material emerges from this second material removal process. A second plurality of micro-lenses may then be formed (step 120) from the second coat of micro-lens suitable material in a manner analogous to the formation of the first plurality of micro-lenses.

One significant variation of the example method described herein comprises application of a first coat of micro-lens suitable material to the surface of a semiconductive circuit, imparting a first lens formation pattern to the first coat of micro-lens suitable material and then removing unwanted material. The step of forming micro-lenses from the first coat of micro-lens suitable material is deferred in this alternative method.

A second or subsequent coat of micro-lens suitable material may then be applied to the semiconductive circuit. A second or subsequent coat of micro-lens suitable material may be subjected to a second or subsequent lens-formation pattern. Unwanted material from the second or subsequent coat of micro-lens suitable material may then be removed. The islands of micro-lens suitable material resulting from these steps may then be used collectively to form a single plurality of micro-lenses.

While this invention has been described in terms of several preferred embodiments, it is contemplated that alternatives, modifications, permutations, and equivalents thereof will become apparent to those skilled in the art upon a reading of the specification and study of the drawings. It is therefore intended that the true spirit and scope of the present invention include all such alternatives, modifications, permutations, and equivalents.

What is claimed is:

1. A method for depositing micro-lenses on a semiconductive circuit comprising the steps of:
successively applying a plurality of coats of micro-lens suitable material to the surface of a semiconductive circuit wherein the current coat is imparted with a succeeding one of a plurality of lens formation patterns;
removing unwanted portions of the current coat of micro-lens suitable material; and
forming a plurality of micro-lenses from the remaining portion of the current coat of micro-lens suitable material.

2. The method of claim 1 wherein the step of imparting the current coat with one of a plurality of lens formation patterns is accomplished by:
placing a formation mask that embodies one of the plurality of lens formation patterns proximate to the current coat of micro-lens suitable material; and
aligning the formation mask to the semiconductive circuit;
irradiating the formation mask.

3. The method of claim 1 wherein the plurality of lens formation patterns are alternate counterparts of each other.

4. A method for depositing micro-lenses on a semiconductive circuit comprising the steps of:
applying a first coat of micro-lens suitable material to the surface of a semiconductive circuit;
imparting a first lens formation pattern onto the first coat of micro-lens suitable material;
removing unwanted portions of the first coat of micro-lens suitable material;
forming a first plurality of micro-lenses from the remaining first coat of microlens suitable material;
applying a second coat of micro-lens suitable material to the semiconductive circuit;
imparting a second lens formation pattern to the second coat of micro-lens suitable material;
removing unwanted portions of the second coat of photo-resist; and
forming a second plurality of micro-lenses from the remaining second coat of micro-lens suitable material.

5. The method of claim 4 wherein the first and second lens formation patterns are alternate counterparts of each other.

6. The method of claim 5 wherein the first and second lens formation patterns comprise rectangular regions in a checkerboard pattern.

7. The method of claim 6 wherein rectangular regions comprise broken corners to avoid continuity with neighboring regions.

8. The method of claim 4 wherein the step of forming the first and second plurality of micro-lenses comprise the steps of:
raising the temperature of the micro-lens suitable material in order to relieve the surface tension thereof;
allowing the micro-lens suitable material to reflow in order to achieve a desired lens focal length; and
reducing the temperature of the micro-lens suitable material in order to preserve the achieved lens focal length.

9. The method of claim 1 wherein the step of applying the first and second coats of micro-lens suitable material comprise the step of spin coating a micro-lens suitable material onto the semiconductive circuit.

10. The method of claim 1 wherein the step of imparting the a first lens formation pattern onto the first coat of micro-lens suitable material comprises the steps of:
placing a first formation mask comprising the first lens formation pattern proximate to the first coat of micro-lens suitable material;
aligning the first formation mask relative to the semiconductive circuit; and
illuminating the first formation mask with radiation.

11. A method for depositing micro-lenses on a semiconductive circuit comprising the steps of:
applying a first coat of micro-lens suitable material to the surface of the semiconductive circuit;
imparting a first lens formation pattern onto the first coat of micro-lens suitable material;
removing unwanted portions of the first coat of micro-lens suitable material;
applying a second coat of micro-lens suitable material to the to the surface of the semiconductive circuit;
imparting a second lens formation pattern onto the second coat of micro-lens suitable material;
removing unwanted portions of the second coat of micro-lens suitable material; and
forming a plurality of micro-lenses from the remaining portions of the first and second coats of micro-lens suitable material.

12. A micro-lens structure comprising:
plurality of micro-lenses disposed proximate to radiation sensitive active regions formed in a semiconductive circuit located wherein each active region is formed within a boundary region perimeter and
wherein each micro-lens is formed from an island of micro-lens suitable material deposited onto the surface of the semiconductive circuit and wherein each island of micro-lens suitable material occupies an area within the boundary region larger than a resolution setback relative to the perimeter of the boundary region.

13. The micro-lens structure of claim 12 wherein the islands of micro-lens suitable material are deposited onto the surface of the semiconductive material and wherein the micro-lenses are formed by:
successively applying a plurality of coats of micro-lens suitable material to the surface of a semiconductive circuit wherein the current coat is imparted with one of a plurality of lens formation patterns;
removing unwanted portions of the current coat of micro-lens suitable material; and
forming a plurality of micro-lenses from the remaining portion of the current coat of micro-lens suitable material.

14. The micro-lens structure of claim 13 wherein the step of imparting the current coat with one of a plurality of lens formation patterns is accomplished by:
placing a formation mask that embodies one of the plurality of lens formation patterns proximate to the current coat of micro-lens suitable material; and
aligning the formation mask to the semiconductive circuit;
irradiating the formation mask.

15. The method of claim 13 wherein the plurality of lens formation patterns are alternate counterparts of each other.

16. The micro-lens structure of claim 12 wherein the islands of micro-lens suitable material are deposited onto the surface of the semiconductive material and wherein the micro-lenses are formed by:
applying a first coat of micro-lens suitable material to the surface of the semiconductive circuit;
imparting a first lens formation pattern onto the first coat of micro-lens suitable material;
removing unwanted portions of the micro-lens suitable material;
forming a first plurality of micro-lenses from the remaining portion of the first coat of micro-lens suitable material;
applying a second coat of photo-resist to the semiconductive circuit;
imparting a second lens formation pattern onto the second coat of micro-lens suitable material;
removing unwanted portions of the micro-lens suitable material; and
forming a second plurality of micro-lenses from the remaining portion of the second coat of micro-lens suitable material.

17. The micro-lens structure of claim 16 wherein application of the first and second coats of from the remaining portion of the first coat of micro-lens suitable material is accomplished through a spin coating process.

18. The micro-lens structure of claim 16 wherein the imparting of a first lens formation pattern onto the first coat of micro-lens suitable material is accomplished by:
placing a first formation mask comprising the first lens formation pattern proximate to the first coat of micro-lens suitable material;
aligning the first formation mask relative to the semiconductive circuit; and
illuminating the first formation mask with radiation.

19. The micro-lens structure of claim 16 wherein the first and second lens formation patterns are alternate counterparts of each other.

20. The micro-lens structure of claim 19 wherein the first and second lens formation patterns comprise rectangular regions in a checkerboard pattern.

21. The micro-lens structure of claim 20 wherein rectangular regions comprise broken corners to avoid continuity with neighboring regions.

22. The method of claim 12 wherein the micro-lenses are formed by:
raising the temperature of the islands of micro-lens suitable material in order to relieve the surface tension thereof;
allowing the islands of micro-lens suitable material to reflow in order to achieve a desired lens focal length; and
reducing the temperature of the islands of micro-lens suitable material in order to preserve the achieved lens focal length.

23. A semiconductive circuit image sensor comprising:
surface;
plurality of radiation sensitive active regions disposed in the surface wherein each active regions is encompassed by a boundary perimeter;
sensing circuitry to sense the state of the plurality of active regions; and
plurality of micro-lenses disposed proximate to and coincident with the plurality of active regions
wherein each micro-lens is formed from an island of micro-lens suitable material deposited onto the surface of the semiconductive circuit and
wherein each island of micro-lens suitable material occupies an area within the boundary region larger than a resolution setback relative to the perimeter of the boundary region.

24. The micro-lens structure of claim 23 wherein the islands of micro-lens suitable material are deposited onto the surface of the semiconductive material and wherein the micro-lenses are formed by:
successively applying a plurality of coats of micro-lens suitable material to the surface of a semiconductive circuit wherein the current coat is imparted with one of a plurality of lens formation patterns;
removing unwanted portions of the current coat of micro-lens suitable material; and
forming a plurality of micro-lenses from the remaining portion of the current coat of micro-lens suitable material.

25. The micro-lens structure of claim 24 wherein the step of imparting the current coat with one of a plurality of lens formation patterns is accomplished by:
placing a formation mask that embodies one of the plurality of lens formation patterns proximate to the current coat of micro-lens suitable material; and
aligning the formation mask to the semiconductive circuit;
irradiating the formation mask.

26. The method of claim 24 wherein the plurality of lens formation patterns are alternate counterparts of each other.

27. The semiconductive image sensor of claim 23 wherein the islands of micro-lens suitable material are deposited onto the surface of the semiconductive material and wherein the micro-lenses are formed by:
applying a first coat of micro-lens suitable material to the surface of the semiconductive circuit;
imparting a first lens formation pattern onto the first coat of the micro-lens suitable material;
removing unwanted portions of the first coat of micro-lens suitable material;
forming a first plurality of micro-lenses from the remaining portion of the first coat of micro-lens suitable material;
applying a second coat of the micro-lens suitable material to the semiconductive circuit;
imparting a second lens formation pattern onto the second coat of the microlens suitable material;
removing unwanted portions of the second coat of micro-lens suitable material; and
forming a second plurality of micro-lenses from the remaining portion of the second coat of micro-lens suitable material.

28. The micro-lens structure of claim 27 wherein application of the first and second coats of micro-lens suitable material is accomplished through a spin coating process.

29. The micro-lens structure of claim 27 wherein imparting a first lens formation pattern onto the first coat of micro-lens suitable material is accomplished by:
placing a first lens formation mask comprising the first lens formation pattern proximate to the first coat of micro-lens suitable material;
aligning the first lens formation mask relative to the semiconductive circuit; and
illuminating the first lens formation mask with radiation.

30. The micro-lens structure of claim 27 wherein the first and second lens formation patterns are alternate counterparts of each other.

31. The micro-lens structure of claim 30 wherein the first and second lens formation patterns comprise rectangular regions in a checkerboard pattern.

32. The micro-lens structure of claim 31 wherein rectangular regions comprise broken corners to avoid continuity with neighboring regions.
